(19) United States
(12) Patent Application Publication
(10) Pub. No.: US 2019/0386481 A1
(43) Pub. Date: Dec. 19, 2019

(54) INPUT CURRENT LIMITING AND INPUT OVER CURRENT PROTECTION FOR POWER CONVERTERS

(71) Applicant: QUALCOMM Incorporated, San Diego, CA (US)

(72) Inventors: Kunhee CHO, San Jose, CA (US); Hector Ivan OPORTA, San Jose, CA (US); Zhaohui ZHU, San Jose, CA (US); Chunping SONG, Sunnyvale, CA (US)

(21) Appl. No.: 16/289,836

(22) Filed: Mar. 1, 2019

Related U.S. Application Data
(60) Provisional application No. 62/685,401, filed on Jun. 15, 2018.

(51) Int. Cl. H02H 7/12; H02M 1/32; H02H 1/00; G01R 19/165

(52) U.S. Cl. CPC H02H 7/1213; H02M 1/32; H02M 2001/0009; G01R 19/16571; H02H 1/0007

(57) ABSTRACT

Certain aspects of the present disclosure generally relate to methods and apparatus for providing input current limiting and input over current protection for a power converter, such as a charge pump converter. One example method of power conversion generally includes sensing an average value associated with an input current for a power supply circuit, sensing an instantaneous value associated with the input current for the power supply circuit, limiting the input current when the sensed average value is greater than a first threshold, and activating over current protection for the power supply circuit when the sensed instantaneous value is greater than a second threshold.

### CROSS-REFERENCE TO RELATED APPLICATIONS

The present application claims the benefit of U.S. Provisional Patent Application Ser. No. 62/685,401, filed Jun. 15, 2018 and entitled “Input Current Limiting and Input Over Current Protection for Power Converters,” which is herein incorporated by reference in its entirety.

### TECHNICAL FIELD

Certain aspects of the present disclosure generally relate to electronic circuits and, more particularly, to input current limiting and input over current protection for power converters.

### BACKGROUND

A voltage regulator ideally provides a desired direct current (DC) output voltage regardless of changes in load current or input voltage. Also known as power converters, voltage regulators may be classified as either linear regulators or switching regulators. While linear regulators tend to be small and compact, many applications may benefit from the increased efficiency of a switching regulator. A switching regulator may be implemented by a switched-mode power supply (SMPS), such as a buck converter, a boost converter, or a charge pump converter.

Power management integrated circuits (power management ICs or PMICs) are used for managing the power requirement of a host system. A PMIC may be used in battery-operated devices, such as mobile phones, tablets, laptops, wearables, etc., to control the flow and direction of electrical power in the devices. The PMIC may perform a variety of functions for the device, such as DC-to-DC conversion, battery charging, power-source selection, voltage scaling, power sequencing, etc. In some cases, the PMIC may include one or more voltage regulators, such as one or more charge pump converters, which may also be referred to as switched-capacitor converters.

### SUMMARY

Certain aspects of the present disclosure generally relate to techniques and apparatus for providing input current limiting and input over current protection for a power converter, such as a charge pump converter.

Certain aspects of the present disclosure provide a method of power conversion. The method generally includes sensing an average value associated with an input current for a power supply circuit, sensing an instantaneous value associated with the input current for the power supply circuit, limiting the input current when the sensed average value is greater than a first threshold, and activating over current protection for the power supply circuit when the sensed instantaneous value is greater than a second threshold.

Certain aspects of the present disclosure provide a power supply circuit. The power supply circuit generally includes a voltage regulator; a current-sensing circuit configured to sense an average value associated with an input current for the voltage regulator and to sense an instantaneous value associated with the input current for the voltage regulator; and logic configured to limit the input current when the sensed average value is greater than a first threshold and to activate over current protection for the power supply circuit when the sensed instantaneous value is greater than a second threshold.

Certain aspects of the present disclosure provide a circuit for power conversion. The apparatus generally includes means for sensing an average value associated with an input current for the circuit, means for sensing an instantaneous value associated with the input current for the circuit, means for limiting the input current when the sensed average value is greater than a first threshold, and means for activating over current protection for the circuit when the sensed instantaneous value is greater than a second threshold.

Certain aspects of the present disclosure provide a current-sensing circuit. The current-sensing circuit generally includes a current-controlled current source; a first resistive element; a second resistive element; a current mirror having a reference current source coupled to an output of the current-controlled current source, a first output branch coupled to a first terminal of the first resistive element, and a second output branch coupled to a first terminal of the second resistive element, a second terminal of the first resistive element and a second terminal of the second resistive element being coupled to a reference potential node of the current-sensing circuit; and a capacitive element coupled in parallel with the first resistive element.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a block diagram of an example device that includes a battery-charging circuit, according to certain aspects of the present disclosure.

FIG. 2 is a block diagram of a power supply circuit having a voltage regulator and supporting circuitry for input current protection of the voltage regulator, in accordance with certain aspects of the present disclosure.

FIG. 3A is an example circuit diagram of a charge pump converter and an input-current-sensing circuit coupled thereto and configured for sensing both average and instantaneous input currents, in accordance with certain aspects of the present disclosure.

FIG. 3B is an example timing diagram of the average and instantaneous input currents sensed by the input-current-sensing circuit of FIG. 3A, in accordance with certain aspects of the present disclosure.

FIG. 4 is an example timing diagram of driver signals for the charge pump converter and output signals of the input-current-sensing circuit of FIG. 3A for input current limit (I_{LIM}) regulation, in accordance with certain aspects of the present disclosure.

FIG. 5 is an example timing diagram of driver signals for the charge pump converter and output signals of the input-current-sensing circuit of FIG. 3A for input over current protection (I_{OCP}), in accordance with certain aspects of the present disclosure.

FIG. 6 is an example timing diagram of driver signals for the charge pump converter and output signals of the input-current-sensing circuit of FIG. 3A, where the I_{OCP} condition is triggered after the instantaneous input current is above an OCP threshold for two consecutive cycles, in accordance with certain aspects of the present disclosure.

FIG. 7 is an example timing diagram of driver signals for a charge pump converter and output signals of the input-sensing circuit of FIG. 3A, illustrating an I_{OCP} condition where the impedance of power transistors in the charge pump converter is temporarily increased, in accordance with certain aspects of the present disclosure.

FIG. 8 is a flow diagram of example operations for power conversion, in accordance with certain aspects of the present disclosure.

### DETAILED DESCRIPTION

Certain aspects of the present disclosure generally relate to methods and apparatus for providing input current limiting and input over current protection for a power converter, such as a charge pump converter.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

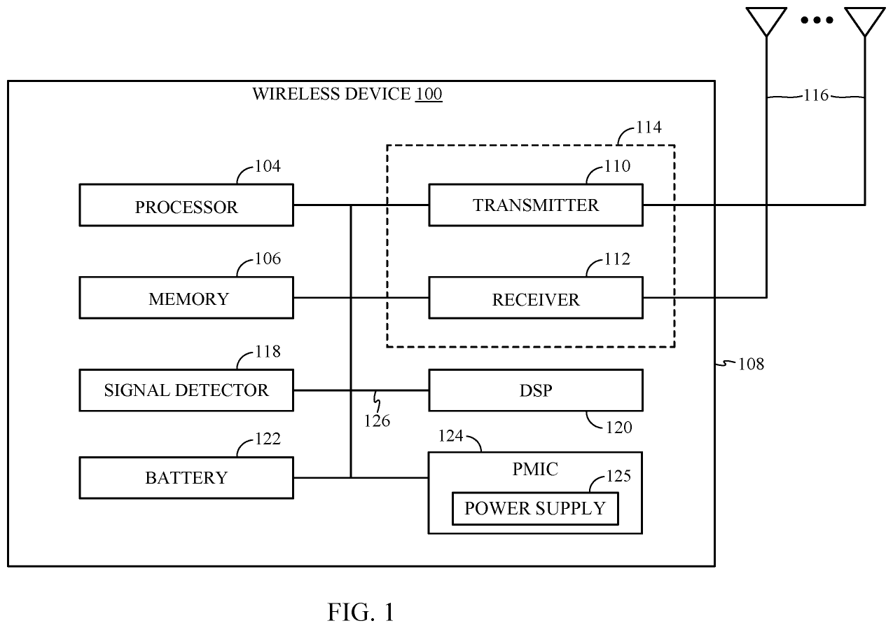

FIG. 1 illustrates an example device 100 in which aspects of the present disclosure may be implemented. For example, the device 100 may be a battery-operated portable device, such as a cellular phone, a personal digital assistant (PDA), a handheld device, a wireless device, a laptop computer, a tablet, a smartphone, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122 used to power the various components of the device 100. The device 100 may also include a power management integrated circuit (power management IC or PMIC) 124 for managing the power from the battery to the various components of the device 100. The PMIC 124 may perform a variety of functions for the device such as DC-to-DC conversion, battery charging, power-source selection, voltage scaling, power sequencing, etc. In certain aspects, the PMIC 124 may include a power supply circuit 125, such as a battery-charging circuit (e.g., a master-slave battery-charging circuit). For certain aspects, the battery-charging circuit may include a charge pump converter or other power converter with input current limiting and input over current protection, as described below. The various components of the device 100 may be coupled together by a bus system 126, which may include a power bus, a control signal bus, and/or a status signal bus in addition to a data bus.

### Example Input Current Limiting and Input Over Current Protection for Charge Pump Converters

A charge pump converter, also referred to as a switched-capacitor converter, is a type of inductorless DC/DC converter that uses one or more capacitors as the energy storage element(s), rather than an inductor (as in the case of switched-mode power supplies). Inductors can be relatively expensive, occupy a relatively large amount of area, and are likely to emit radio frequency (RF) energy. Charge pump converters operate by transferring the charge from a flying capacitor (C_{FLY}) to an output capacitor (C_{OUT}) by using sets of switches that are activated/deactivated periodically to charge and discharge the flying capacitor.

A charge pump converter may be used as a standalone converter or may be used in conjunction with another converter, which may be referred to as a companion converter. For example, in order to charge the battery (e.g., battery 122) in a portable device, a battery-charging circuit may be utilized. For certain aspects, the battery-charging circuit may be part of a power supply circuit 125 residing in a PMIC (e.g., PMIC 124). The battery-charging circuit may comprise, for example, one or more charge pump converters and/or one or more switched-mode power supplies (e.g., a buck converter). The battery-charging circuit may comprise two or more parallel charging circuits, each capable of charging the battery, which may be connected together and to the battery in an effort to provide fast charging of the battery. Example parallel battery-charging circuits are described in U.S. Pat. No. 9,590,436 to Sporck et al., filed Apr. 11, 2014 and entitled “Master-Slave Multi-Phase Charging.” Conventional charging circuits, like those described in U.S. Pat. No. 9,590,436, for a parallel charger may use buck converter topologies. However, one of the buck converters may be replaced with a charge pump converter in some parallel charging circuits.

Charger applications may utilize input current limit (I_{LIM}) control to protect the cable of a wall adapter, for example, from collapsing due to the heat caused by excessive load conditions above the cable's current carrying capacity. Unlike a buck converter topology with an inductor, in a divide-by-two (DIV2) charge pump architecture, given the nature thereof, a singular large current spike is anticipated during current limit conditions when phases are skipped to limit input current because of the absence of the inductor. This create challenges to differentiate normal current limit conditions during load transients from real system fault conditions, such as output (battery) short circuit conditions.

In example conventional charge pump architectures, the charge pump uses an overvoltage protection field-effect transistor (OVPFET) and its control circuits to protect from input current fault conditions (e.g., high input current) and to regulate the average input current. However, an OVPFET typically occupies very large area (e.g., >1 mm², due to operating in potential high-voltage conditions) and degrades the efficiency of the converter due to the drain-to-source on-resistance (R_{ds.on}) drop through the OVPFET. Furthermore, a relatively large shunt capacitor may be connected to a node between the OVPFET and the charge pump converter, which increases the area, as well as the cost of the power supply circuit.

Certain aspects of the present disclosure provide input current limiting and input over current protection (OCP) without using an OVPFET or its associated control circuitry. Input current limit (I_{LIM}) control involves regulating the average value of the input current according to a reference level (I_{LIM.REF}). Input OCP (I_{OCP}) generally refers to protecting a circuit against a large instantaneous current flow due to a very high load current or output short circuit condition. Input current limiting and input OCP may collectively may referred to herein as “input current protection.”

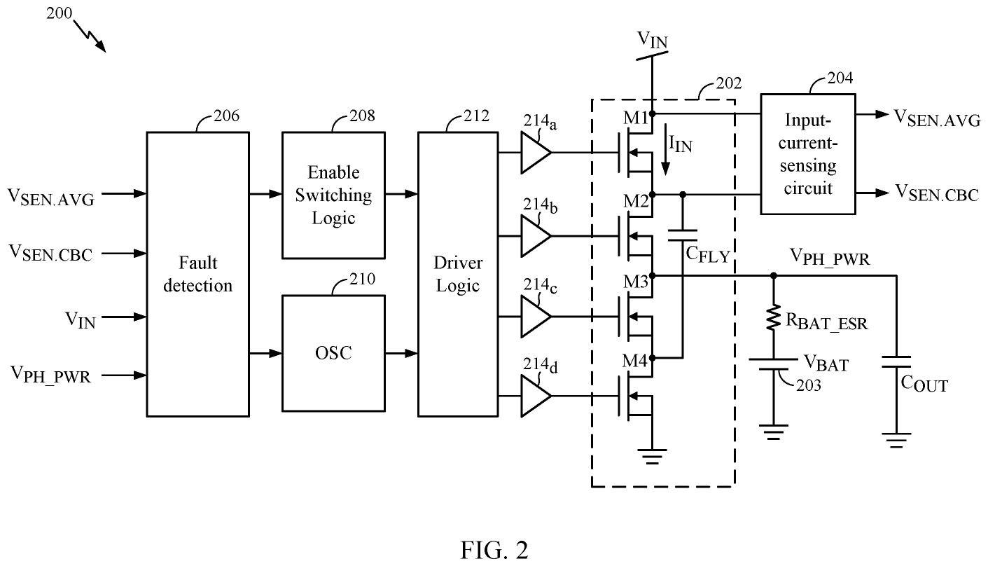

FIG. 2 is a block diagram of a power supply circuit 200 having a voltage regulator 202 and supporting circuitry for input current protection of the voltage regulator, in accordance with certain aspects of the present disclosure. For certain aspects, the power supply circuit 200 may be employed as the power supply circuit 125 in a PMIC 124, as illustrated in FIG. 1. The voltage regulator 202 may be implemented as a charge pump converter as illustrated in FIG. 2, although any of various suitable inductorless voltage regulator topologies may be used.

The voltage regulator 202 may include four transistors M1, M2, M3, and M4, which may be implemented by n-type metal-oxide-semiconductor (NMOS) power field-effect transistors (FETs), as shown. The drain of transistor M1 may be coupled to a power supply rail (labeled “V_{IN}”), and the source of transistor M4 may be coupled to a reference potential node (e.g., electrical ground) for the power supply circuit 200. The source of transistor M2 may be coupled to the drain of transistor M3, to a first terminal of a battery 203, and to a first terminal of an output capacitor (C_{OUT}) at a node labeled “V_{PH_PWR}”. A second terminal of the battery 203 and a second terminal of C_{OUT} may be coupled to the reference potential node, such that the battery and C_{OUT} are in parallel. For certain aspects, the battery 203 may be the battery 122 in the device 100 of FIG. 1. The equivalent series resistance (ESR) of the battery 203 is represented by the resistive element R_{BAT_ESR}. The source of the transistor M1 and the drain of the transistor M2 may be coupled to a first terminal of a flying capacitor (C_{FLY}), while the source of the transistor M3 and the drain of the transistor M4 may be coupled to a second terminal of C_{FLY}.

The power supply circuit 200 also includes an input-current-sensing circuit 204, fault detection logic 206, enable switching logic 208, an oscillator 210 (labeled “OSC”), driver logic 212, and drivers 214a, 214b, 214c, and 214d (collectively referred to herein as “drivers 214”). The input-current-sensing circuit 204 is configured to sense both the average and instantaneous input current (I_{IN}) of the voltage regulator 202. Although illustrated in FIG. 2 as being coupled to the drain and source of transistor M1, the input current may be sensed via any of the transistors M1-M4 in the voltage regulator 202. The average input current information (e.g., V_{SEN.AVG}) and the instantaneous input current information (e.g., V_{SEN.CBC}) are fed back into the fault detection logic 206, along with V_{IN} and V_{PH_PWR}. The fault detection logic 206 is configured to control the voltage regulator 202 (e.g., the charge pump converter) to protect the circuit from any fault conditions. Thus, the fault detection logic 206 may be coupled to and may generate output signals to control the enable switching logic 208 and/or the oscillator 210. The oscillator 210 may generate a periodic signal output to the driver logic 212 to control the switching frequency of the voltage regulator 202 and, hence, set the switching cycle. The driver logic 212 may generate driver signals with different phases for outputting to the drivers 214 to control the transistors M1-M4 according to the switching frequency. Based on the output of the fault detection logic 206, the enable switching logic 208 may generate one or more output signals to control the driver logic 212 to enable or disable one or more of the driver signals generated thereby. The algorithm used by the fault detection logic 206 to determine a fault condition and provide input current protection is described in more detail below.

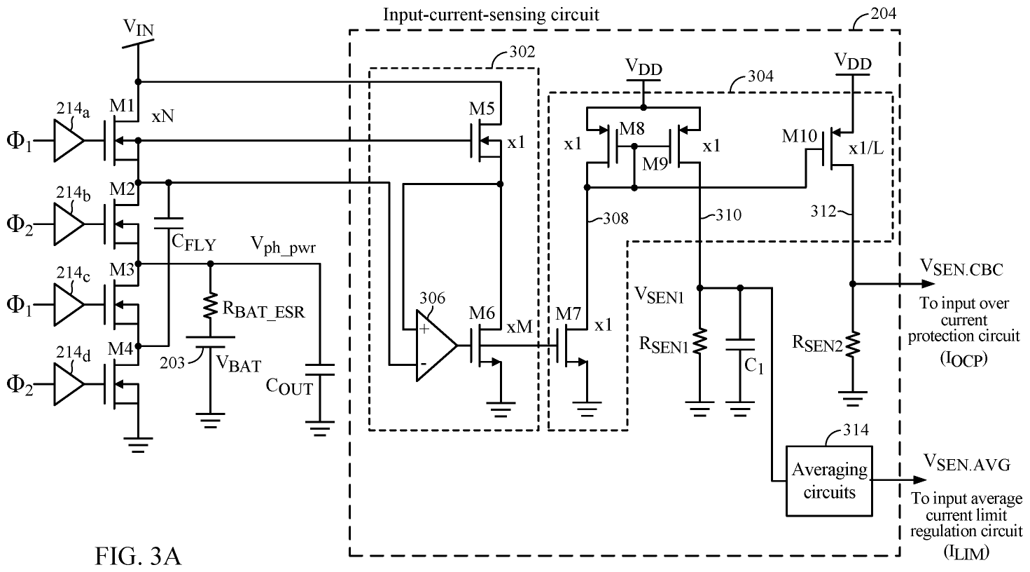

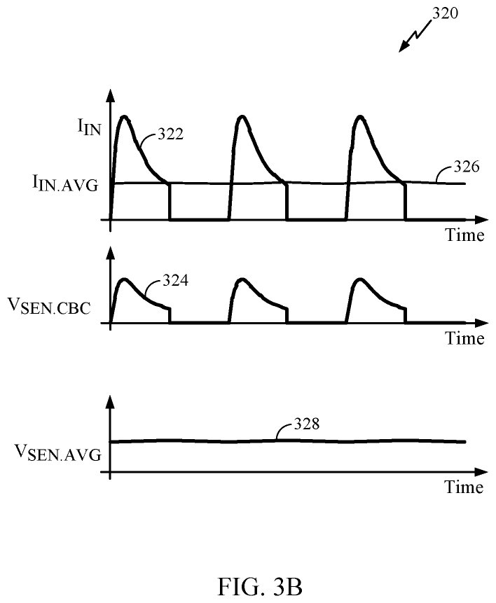

To implement a protection circuit with I_{LIM} and I_{OCP} capabilities, two input current values may be sensed. Namely, these are the average DC input current (I_{IN.AVG}) and the instantaneous input current (I_{IN}). The input current can be sensed by adding current sensing circuitry (e.g., the input-current-sensing circuit 204) at any of the power FETs in the charge pump structure. FIG. 3A shows the input-current-sensing circuit 204 coupled to the upper high-side FET (referred to as “HS_TOP FET”) of the charge pump architecture. With aspects of the present disclosure, any bulk OVPFET need not be included to sense the input current.

The example input-current-sensing circuit 204 in FIG. 3A includes a current-sensing amplifier, which may include a current-controlled current source 302, a current mirror 304, and resistive elements (e.g., resistors R_{SEN1} and R_{SEN2}). The current-controlled current source 302 may include an amplifier 306, a replica transistor M5 (e.g., smaller than the power transistor, such as transistor M1, by a size ratio 1:N), and a dependent current source transistor M6 controlled by the output of the amplifier 306. In this manner, the current through the dependent current source transistor M6 will be regulated at, for example, N times smaller than the current through the power transistor (e.g., transistor M1). The current mirror 304 includes a reference branch 308, a first output branch 310, and a second output branch 312. The reference branch 308 includes a transistor M7 driven with the same voltage as the dependent current source transistor M6. For certain aspects, the reference branch transistor M7 will be M times smaller than the dependent current source transistor M6, such that the current in the reference branch 308 will be held at M times smaller than the current through the replica transistor M5. As shown, the current mirror 304 is implemented as a 1:1:1/L current mirror, such that the current in the first output branch 310 matches the current in the reference branch 308, but the current in the second output branch 312 may be L times smaller than the current in the reference branch 308. These currents in the output branches 310, 312 flow through respective sensing resistive elements (e.g., resistors R_{SEN1} and R_{SEN2}), such that a voltage indicative of the current can be sent to a logic circuit (e.g., fault detection logic 206) or further processed (e.g., filtered by a shunt capacitive element with capacitance C₁ and/or an optional averaging circuit 314) before sending to the logic circuit.

The sensed cycle-by-cycle (CBC) voltage (V_{SEN.CBC}) 324 follows the instantaneous I_{N} waveform 322 in the timing diagram 320 of FIG. 3B, and the sensed average voltage (V_{SEN.AVG}) 328 represents the average DC value of I_{IN} (I_{IN.AVG} 326) with limited bandwidth (due to the capacitance C₁ and/or the optional averaging circuit 314, which may include one or more active filters, for example). In addition, only a single current-sensing (I_{SEN}) amplifier is used for both I_{IN.AVG} and instantaneous I_{N} information. V_{SEN.CBC} will be used for the I_{OCP} circuit, and V_{SEN.AVG} will be used for the I_{LIM} circuit.

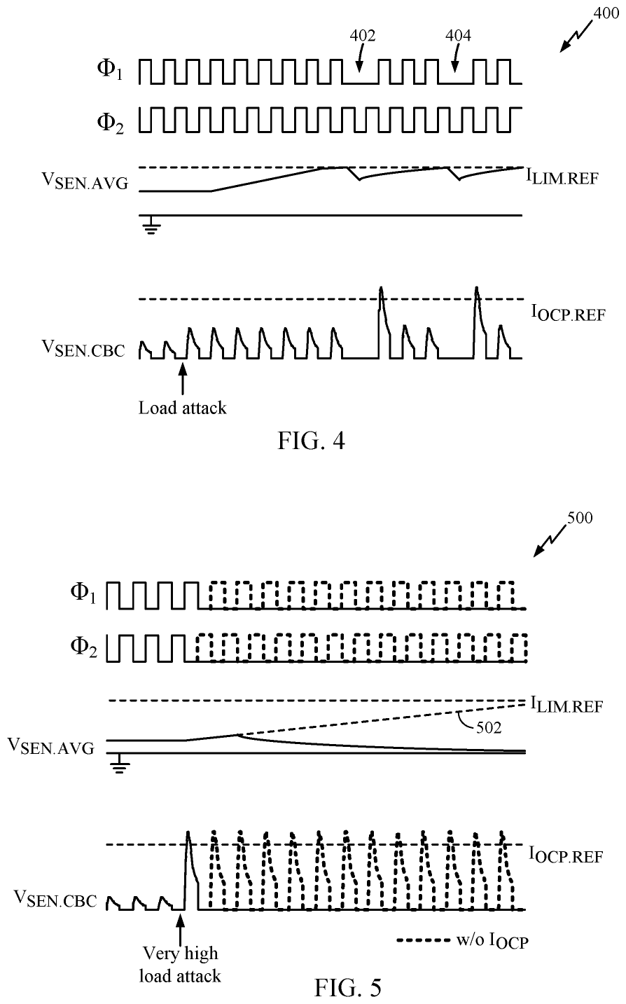

In a 2:1 charge pump architecture, the input current (I_{N}) is about half of the output current (I_{OUT}). For input current limit (I_{LIM}) regulation as illustrated in the timing diagram 400 of FIG. 4, the I_{IN} can be regulated by V_{PH_PWR} since I_{OUT} is set by (V_{PH_PWR}−V_{BAT})/R_{BAT_ESR}, where R_{BAT_ESR} is the equivalent series resistance of the battery 203. If V_{SEN.AVG}, which corresponds to the average value of I_{IN}, is larger than the reference level (I_{LIM.REF}), the input current can be limited by limiting or skipping the clock phase 1 signal (Φ₁) for driving the transistors M1 and M3 with the drivers 214a and 214c, respectively, because of the output voltage (V_{PH_PWR}) drop. This drop decreases I_{OUT} and reduces I_{IN}, as shown by the corresponding V_{SEN.CBC} waveform. In the timing diagram 400, pulses in the clock phase 1 signal (Φ₁) are skipped at times 402 and 404, due to V_{SEN.AVG} meeting or exceeding I_{LIM.REF}. In addition, skipping both Φ₁ and Φ₂ (the clock phase 2 signal for driving the transistors M2 and M4 with the drivers 214b and 214d, respectively) can be used.

V_{SEN.AVG} may not sufficiently protect the charge pump converter from inrush current immediately due to a limited bandwidth, as shown by the slowly rising dotted line 502 in the timing diagram 500 of FIG. 5. Thus, instantaneous I_{IN} information may be utilized instead to implement I_{OCP}. This can be achieved by using V_{SEN.CBC}, which may not be significantly filtered and, thus, does not suffer from limited bandwidth. When V_{SEN.CBC} exceeds the threshold (I_{OCP.REF}), for example, due to a high load attack, then at least a portion of the charge pump converter may be shut off or the impedance of the charge pump converter may be changed to protect the components of the converter. In this manner, the charge pump converter can be protected almost immediately when a high load attack occurs. In the timing diagram 500 of FIG. 5, both Φ₁ and Φ₂ are shut off once the high load attack occurs and is detected by V_{SEN.CBC} exceeding I_{OCP.REF}.

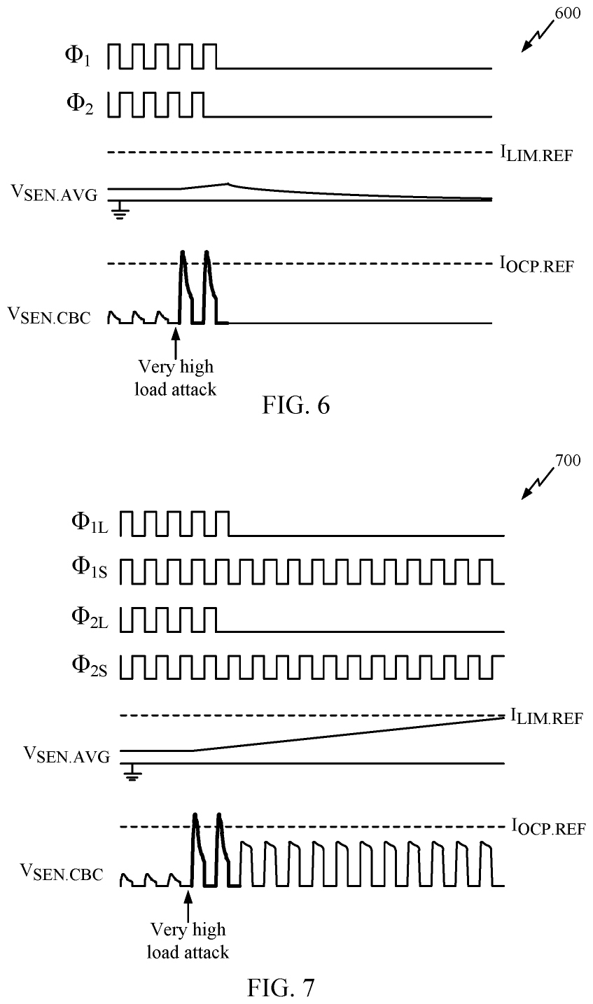

However, in the I_{LIM} condition, the input current can show high peaking right after skipping or limiting Φ₁, due to a large inrush current when Φ₁ is reactivated, as illustrated by the corresponding V_{SEN.CBC} waveform in FIG. 4. This high peaking could trigger an unwanted I_{OCP} condition and lead to shutting off the charge pump prematurely. Therefore, to distinguish between I_{LIM} and I_{OCP} for certain aspects, an I_{OCP} condition may only be indicated when V_{SEN.CBC} is above I_{OCP.REF} for two or more consecutive cycles, as illustrated in the timing diagram 600 of FIG. 6. If only one cycle of an I_{OCP} condition occurs, then logic (e.g., the fault detection logic 206) in the power supply circuit 200 may ignore the I_{OCP} condition and treat this as an I_{LIM} condition. If two or more consecutive cycles of I_{OCP} are detected, then the power supply circuit 200 regards this as a true I_{OCP} condition and protects the voltage regulator 202.

There are several ways to protect against an OCP condition. As stated above, an OCP condition can be protected against by effectively shutting off the voltage regulator (e.g., by disabling the driver signals to the drivers 214). Alternatively, different kinds of protection can be used. One of these alternative methods involves increasing the impedance of the power stage. For an example, if an OCP condition is detected (e.g., by two or more consecutive I_{OCP} counts), the impedance of the output stage can be increased by reducing the size of the power stage, which reduces the peaking of the input current. Reducing the size of the power stage may involve driving smaller transistors with higher on-resistance during an OCP condition, compared to driving larger transistors with smaller on-resistance during normal operation of the voltage regulator.

FIG. 7 is a timing diagram 700 illustrating example waveforms corresponding to such an impedance change upon detection of an OCP condition. Φ_{OL} and Φ_{2L} represent the driver signals for driving relatively larger power FETs, whereas Φ_{1S} and Φ_{2S} represent the driver signals for driving relatively smaller power FETs (e.g., ¼ size of larger power FET size). After a few cycles of driving the high impedance FETs, the power supply circuit may be returned to driving the smaller impedance FETs, at least until another OCP condition is detected.

Certain aspects of the present disclosure may protect the voltage regulator from high peak and average input current that can damage or reduce the lifespan of the converter. I_{OCP} protects the high peak/average input current, and I_{LIM} regulates the average input current. I_{OCP} and I_{LIM} can function together without interfering with each other. Both average input current sensing and instantaneous current sensing may be implemented for I_{LIM} and I_{OCP} with several advantages and benefits. By using I_{LIM} and I_{OCP} as described above, the voltage regulator 202 can be protected from a high load attack and can regulate I_{N} adequately according to a target value (e.g., I_{LIM.REF}). For example, because the use of an OVPFET is avoided, the current-sensing circuits described herein occupy less die area than other conventional circuits employing a bulky OVPFET, but still implement input current fault protection circuit. In addition, a single current-sensing circuit can be used for both I_{LIM} and I_{OCP} functions concurrently. Moreover, the current-sensing circuit described herein utilizes small circuits, mainly composed of low-voltage cells. Furthermore, test time during fabrication can be shorter because the offset trimming of the current-sensing amplifier can be done once for both I_{LIM} and I_{OCP} functions. As an additional benefit, a pin typically used in an integrated circuit (IC) implementing the power supply circuit (e.g., the PMIC 124) for access to a node between the OVPFET and the voltage regulator can be removed. Moreover, because an OVPFET is not used, the typical large capacitor connected to this node in conventional solutions can be removed, saving area. Furthermore, aspects of the present disclosure do not suffer from a loop stability issue.

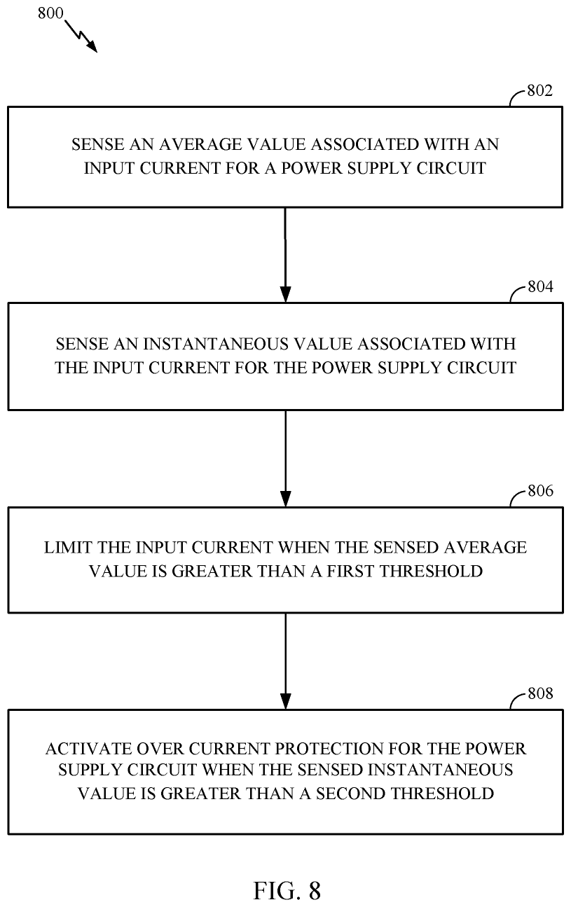

FIG. 8 is a flow diagram of example operations 800 for power conversion, in accordance with certain aspects of the present disclosure. The operations 800 may be performed, for example, by a power supply circuit (e.g., the power supply circuit 200), which may include a voltage regulator (e.g., the voltage regulator 202) and supporting circuitry (e.g., the input-current-sensing circuit 204, the fault detection logic 206, the enable switching logic 208, the oscillator 210, the driver logic 212, and the drivers 214) capable of providing input current protection for the voltage regulator.

The operations 800 may begin, at block 802, with the power supply circuit sensing an average value associated with an input current (e.g., I_{IN}) for the power supply circuit. At block 804, the power supply circuit may sense an instantaneous value associated with the input current for the power supply circuit. At block 806, the power supply circuit may limit the input current when the sensed average value is greater than a first threshold (e.g., I_{LIM.REF}). At block 808, the power supply circuit may activate over current protection for the power supply circuit when the sensed instantaneous value is greater than a second threshold (e.g., I_{OCP.REF}).

According to certain aspects, the activating at block 808 entails activating the over current protection for the power supply circuit when the sensed instantaneous value is greater than the second threshold for at least two consecutive cycles of the power supply circuit.

According to certain aspects, sensing the average value at block 802 involves sensing an average voltage (e.g., V_{SEN.AVG}) representative of the average value of the input current for the power supply circuit. For certain aspects, sensing the instantaneous value at block 804 includes sensing an instantaneous voltage (e.g., V_{SEN.CBC}) representative of the instantaneous value of the input current for the power supply circuit.

According to certain aspects, the power supply circuit comprises a charge pump converter (e.g., the charge pump converter illustrated in FIGS. 2 and 3).

According to certain aspects, activating the over current protection at block 808 entails shutting off the power supply circuit. For certain aspects, shutting off the power supply circuit involves disabling drivers (e.g., drivers 214) in the power supply circuit.

According to certain aspects, activating the over current protection at block 808 includes increasing an impedance of the power supply circuit. For certain aspects, increasing the impedance of the power supply circuit involves discontinuing driving a first type of transistor with a relatively smaller impedance and driving a second type of transistor with a relatively larger impedance. In this case, the power supply circuit includes both the first type of transistor and the second type of transistor.

According to certain aspects, limiting the input current at block 806 entails skipping driving at least one transistor of the power supply circuit for at least one cycle of the power supply circuit.

According to certain aspects, sensing the average value at block 802 involves sensing an average voltage (e.g., V_{SEN.AVG}) representative of the average value of the input current for the power supply circuit. In this case, the average voltage may be generated by a current-sensing circuit (e.g., input-current-sensing circuit 204) in the power supply circuit. The current-sensing circuit may include a current-controlled current source (e.g., current-controlled current source 302); a first resistive element (e.g., resistor with resistance R_{SEN1}); a current mirror (e.g., current mirror 304) having a reference current source (e.g., comprising transistor M7) coupled to an output of the current-controlled current source and having a first output branch (e.g., output branch 310) coupled to a first terminal of the first resistive element, a second terminal of the first resistive element being coupled to a reference potential node (e.g., electrical ground) of the current-sensing circuit; and a capacitive element (e.g., capacitor with capacitance C₁) coupled in parallel with the first resistive element. In this case, the average voltage may be generated across the first resistive element and the capacitive element. For certain aspects, sensing the instantaneous value includes sensing an instantaneous voltage (e.g., V_{SEN CBC}) representative of the instantaneous value of the input current for the power supply circuit. For certain aspects, the instantaneous voltage is generated by the current-sensing circuit. For certain aspects, the current-sensing circuit further includes a second resistive element (e.g., resistor with resistance R_{SEN2}). For certain aspects, the current mirror has a second output branch (e.g., output branch 312) coupled to a first terminal of the second resistive element. For certain aspects, a second terminal of the second resistive element is coupled to the reference potential node of the current-sensing circuit. For certain aspects, the instantaneous voltage is generated across the second resistive element.

Certain aspects of the present disclosure provide a current-sensing circuit (e.g., the input-current-sensing circuit 204). The current-sensing circuit generally includes a current-controlled current source (e.g., current source 302); a first resistive element (e.g., resistor with resistance R_{SEN1}); a second resistive element (e.g., resistor with resistance R_{SEN2}); a current mirror (e.g., current mirror 304) having a reference current source (e.g., transistor M7) coupled to an output of the current-controlled current source, a first output branch (e.g., first output branch 310) coupled to a first terminal of the first resistive element, and a second output branch (e.g., second output branch 312) coupled to a first terminal of the second resistive element, a second terminal of the first resistive element and a second terminal of the second resistive element being coupled to a reference potential node (e.g., electrical ground) of the current-sensing circuit; and a capacitive element (e.g., capacitor with capacitance C₁) coupled in parallel with the first resistive element.

According to certain aspects, a first output of the current-sensing circuit is coupled to the first terminal of the first resistive element and is configured to sense an average value of an input current applied to the current-controlled current source. For certain aspects, a second output of the current-sensing circuit is coupled to the first terminal of the second resistive element and is configured to sense an instantaneous value of the input current applied to the current-controlled current source.

According to certain aspects, the current-controlled current source includes a first transistor, a second transistor having a drain coupled to a source of the first transistor, and an amplifier having an output coupled to a gate of the second transistor and a first input coupled to the drain of the second transistor. For certain aspects, a drain of the first transistor is coupled to a first input of the current-sensing circuit, a gate of the first transistor is coupled to a second input of the current-sensing circuit, and a second input of the amplifier is coupled to a third input of the current-sensing circuit. For certain aspects, the reference current source includes a third transistor having a gate coupled to the gate of the second transistor. In this case, the second transistor may have a larger size than the third transistor.

According to certain aspects, the current-sensing circuit further includes an averaging circuit having an input coupled to the first terminal of the first resistive element and an output coupled to a first output of the current-sensing circuit. In this case, the first terminal of the second resistive element may be coupled to a second output of the current-sensing circuit.

According to certain aspects, the first output branch includes a first transistor having a drain coupled to the first terminal of the first resistive element. For certain aspects, the second output branch includes a second transistor having a drain coupled to the first terminal of the second resistive element. For certain aspects, the second transistor has a smaller size than the first transistor.

Certain aspects of the present disclosure provide a charge pump converter comprising a current-sensing circuit. The current-sensing circuit generally includes a current-controlled current source; a first resistive element; a second resistive element; a current mirror having a reference current source coupled to an output of the current-controlled current source, a first output branch coupled to a first terminal of the first resistive element, and a second output branch coupled to a first terminal of the second resistive element, a second terminal of the first resistive element and a second terminal of the second resistive element being coupled to a reference potential node of the current-sensing circuit; and a capacitive element coupled in parallel with the first resistive element.

Certain aspects of the present disclosure provide a charge pump converter. The charge pump converter generally includes a first capacitive element (e.g., C_{FLY}); a first transistor (e.g., transistor M1); a second transistor (e.g., transistor M2) coupled in series with the first transistor and coupled to a first terminal of the first capacitive element; a third transistor (e.g., transistor M3) coupled in series with the second transistor; a fourth transistor (e.g., transistor M4) coupled in series with the third transistor and coupled to a second node of the first capacitive element; and a current-sensing circuit (e.g., input-current-sensing circuit 204) having a plurality of inputs coupled to one of the first, second, third, and fourth transistors. The current-sensing circuit generally includes a current-controlled current source; a first resistive element; a second resistive element; a current mirror having a reference current source coupled to an output of the current-controlled current source, a first output branch coupled to a first terminal of the first resistive element, and a second output branch coupled to a first terminal of the second resistive element, a second terminal of the first resistive element and a second terminal of the second resistive element being coupled to a reference potential node of the current-sensing circuit; and a second capacitive element coupled in parallel with the first resistive element.

According to certain aspects, a first output of the current-sensing circuit is coupled to the first terminal of the first resistive element and is configured to sense an average value of an input current applied to the current-controlled current source. For certain aspects, a second output of the current-sensing circuit is coupled to the first terminal of the second resistive element and is configured to sense an instantaneous value of the input current applied to the current-controlled current source. For certain aspects, the charge pump converter further includes a driver coupled to each of the first, second, third, and fourth transistors; and logic coupled between the first and second outputs of the current-sensing circuit and at least one of the drivers. The logic may be configured to control the at least one of the drivers based on at least one of the average value or the instantaneous value of the input current. For certain aspects, the input current is based on a current through the first transistor. For certain aspects, the drivers are configured to activate the first and third transistors during a first phase and to activate the second and fourth transistor during a second phase, during normal operation of the charge pump converter.

Certain aspects of the present disclosure provide a power management integrated circuit (PMIC) comprising at least a portion of the charge pump converter described above.

Certain aspects of the present disclosure provide a battery-charging circuit comprising the charge pump converter described above.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

For example, means for sensing an average value and/or means for sensing an instantaneous value associated with an input current may be implemented by a current-sensing circuit (e.g., the input-current-sensing circuit 204 as depicted in FIGS. 2 and 3). Means for limiting the input current and/or means for activating over current protection may be implemented, for example, by supporting circuitry for a power supply circuit (e.g., fault detection logic 206, enable switching logic 208, oscillator 210, driver logic 212, and/or one or more drivers 214 as illustrated in FIG. 2).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, ca-a-a, a-a-b, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

1. A method of power conversion, comprising:
sensing an average value associated with an input current for a power supply circuit;
sensing an instantaneous value associated with the input current for the power supply circuit;
limiting the input current when the sensed average value is greater than a first threshold; and
activating over current protection for the power supply circuit when the sensed instantaneous value is greater than a second threshold.

2. The method of claim 1, wherein the activating comprises activating the over current protection for the power supply circuit when the sensed instantaneous value is greater than the second threshold for at least two consecutive cycles of the power supply circuit.

3. The method of claim 1, wherein sensing the average value comprises sensing an average voltage representative of the average value of the input current for the power supply circuit and wherein sensing the instantaneous value comprises sensing an instantaneous voltage representative of the instantaneous value of the input current for the power supply circuit.

4. The method of claim 1, wherein the power supply circuit comprises a charge pump converter.

5. The method of claim 1, wherein activating the over current protection comprises shutting off the power supply circuit.

6. The method of claim 1, wherein activating the over current protection comprises increasing an impedance of the power supply circuit.

7. The method of claim 6, wherein increasing the impedance of the power supply circuit comprises discontinuing driving a first type of transistor with a relatively smaller impedance and driving a second type of transistor with a relatively larger impedance, the power supply circuit including both the first type of transistor and the second type of transistor.

8. The method of claim 1, wherein limiting the input current comprises skipping driving at least one transistor of the power supply circuit for at least one cycle of the power supply circuit.

9. The method of claim 1, wherein sensing the average value comprises sensing an average voltage representative of the average value of the input current for the power supply circuit, wherein the average voltage is generated by a current-sensing circuit in the power supply circuit.

10. The method of claim 9, wherein:
sensing the instantaneous value comprises sensing an instantaneous voltage representative of the instantaneous value of the input current for the power supply circuit; and
the instantaneous voltage is generated by the current-sensing circuit.

11. A power supply circuit comprising:
a voltage regulator;
a current-sensing circuit configured to sense an average value associated with an input current for the voltage regulator and to sense an instantaneous value associated with the input current for the voltage regulator; and
logic configured to limit the input current when the sensed average value is greater than a first threshold and to activate over current protection for the power supply circuit when the sensed instantaneous value is greater than a second threshold.

12. The power supply circuit of claim 11, wherein the logic is configured to activate the over current protection for the power supply circuit when the sensed instantaneous value is greater than the second threshold for at least two consecutive cycles of the power supply circuit.

13. The power supply circuit of claim 11, wherein the current-sensing circuit is configured to sense the average value by sensing an average voltage representative of the average value of the input current for the voltage regulator and wherein the current-sensing circuit is configured to sense the instantaneous value by sensing an instantaneous voltage representative of the instantaneous value of the input current for the voltage regulator.

14. The power supply circuit of claim 11, wherein the voltage regulator comprises a charge pump converter.

15. The power supply circuit of claim 11, wherein the logic is configured to activate the over current protection for the power supply circuit by shutting off the voltage regulator.

16. The power supply circuit of claim 11, wherein the logic is configured to activate the over current protection for the power supply circuit by increasing an impedance of the voltage regulator.

17. The power supply circuit of claim 16, wherein the voltage regulator comprises a first type of transistor with a relatively smaller impedance and a second type of transistor with a relatively larger impedance, wherein increasing the impedance of the power supply circuit comprises discontinuing driving the first type of transistor and driving the second type of transistor.

18. The power supply circuit of claim 11, wherein the voltage regulator comprises at least one transistor and wherein the logic is configured to limit the input current by skipping driving the at least one transistor for at least one cycle of the power supply circuit.

19. The power supply circuit of claim 11, wherein the current-sensing circuit is configured to sense the average value by sensing an average voltage representative of the average value of the input current for the voltage regulator and wherein the current-sensing circuit comprises:
a current-controlled current source;
a first resistive element;
a current mirror having a reference current source coupled to an output of the current-controlled current source and having a first output branch coupled to a first terminal of the first resistive element, a second terminal of the first resistive element being coupled to a reference potential node of the current-sensing circuit; and
a capacitive element coupled in parallel with the first resistive element, wherein the average voltage is generated across the first resistive element and the capacitive element.

20. The power supply circuit of claim 19, wherein:
the current-sensing circuit is configured to sense the instantaneous value by sensing an instantaneous voltage representative of the instantaneous value of the input current for the voltage regulator;
the current-sensing circuit further comprises a second resistive element;
the current mirror has a second output branch coupled to a first terminal of the second resistive element;
a second terminal of the second resistive element is coupled to the reference potential node of the current-sensing circuit; and
the instantaneous voltage is generated across the second resistive element.

21. A circuit for power conversion, comprising:
means for sensing an average value associated with an input current for the circuit;
means for sensing an instantaneous value associated with the input current for the circuit;
means for limiting the input current when the sensed average value is greater than a first threshold; and
means for activating over current protection for the circuit when the sensed instantaneous value is greater than a second threshold.

22. A current-sensing circuit comprising:
a current-controlled current source;
a first resistive element;
a second resistive element;
a current mirror having a reference current source coupled to an output of the current-controlled current source, a first output branch coupled to a first terminal of the first resistive element, and a second output branch coupled to a first terminal of the second resistive element, a second terminal of the first resistive element and a second terminal of the second resistive element being coupled to a reference potential node of the current-sensing circuit; and a capacitive element coupled in parallel with the first resistive element.

23. The current-sensing circuit of claim 22, wherein a first output of the current-sensing circuit is coupled to the first terminal of the first resistive element and is configured to sense an average value of an input current applied to the current-controlled current source.

24. The current-sensing circuit of claim 23, wherein a second output of the current-sensing circuit is coupled to the first terminal of the second resistive element and is configured to sense an instantaneous value of the input current applied to the current-controlled current source.

25. The current-sensing circuit of claim 22, wherein the current-controlled current source comprises:
a first transistor;
a second transistor having a drain coupled to a source of the first transistor; and
an amplifier having an output coupled to a gate of the second transistor and a first input coupled to the drain of the second transistor.

26. The current-sensing circuit of claim 25, wherein a drain of the first transistor is coupled to a first input of the current-sensing circuit, wherein a gate of the first transistor is coupled to a second input of the current-sensing circuit, and wherein a second input of the amplifier is coupled to a third input of the current-sensing circuit.

27. The current-sensing circuit of claim 25, wherein the reference current source comprises a third transistor having a gate coupled to the gate of the second transistor and wherein the second transistor has a larger size than the third transistor.

28. The current-sensing circuit of claim 22, further comprising an averaging circuit having an input coupled to the first terminal of the first resistive element and an output coupled to a first output of the current-sensing circuit, wherein the first terminal of the second resistive element is coupled to a second output of the current-sensing circuit.

29. The current-sensing circuit of claim 22, wherein the first output branch comprises a first transistor having a drain coupled to the first terminal of the first resistive element and wherein the second output branch comprises a second transistor having a drain coupled to the first terminal of the second resistive element.

30. The current-sensing circuit of claim 29, wherein the second transistor has a smaller size than the first transistor.
